(19) United States
(12) Patent Application Publication
(10) Pub. No.: US 2007/0016840 A1
(43) Pub. Date: Jan. 18, 2007

(54) Method for checking the safety and reliability of software-based electronic system

(76) Inventors: Thomas Zurawka, Stuttgart (DE); Joerg Schaeuffele, (US)

Correspondence Address: KENYON & KENYON LLP, ONE BROADWAY, NEW YORK, NY, 10004, US

(21) Appl. No.: 10/561,567

(22) PCT Filed: Jun. 24, 2004
(86) PCT No.: PCT/DE04/01317

§ 371 Date: Aug. 25, 2006

(30) Foreign Application Priority Data
Jun. 24, 2003 (DE) 103 28 239.4

(51) Int. Cl. H03M 13/00

(52) U.S. Cl. 714/776

(57) ABSTRACT

A method for checking the safety and reliability of software-based electronic systems, using a reliability function for checking the functions of the system that are called for, based on the hardware components of the system required for this. In this connection it is provided that a reliability function is determined for calculating the reliability of at least one of the required functions of the system, and an additional reliability function is determined for calculating the reliability of at least one of the safety functions of the system, in the determination of these reliability functions, software components of the system being taken into consideration with the aid of hardware components onto which these software components are distributed. This makes possible the early valuation of different monitoring concepts for such systems, and of functions of these systems which are implemented by software and hardware.

### FIELD OF THE INVENTION

The present invention relates to a method for checking the safety and reliability of software-based electronic systems, using a reliability function for checking the functions of the system that are called for, based on the hardware components of the system required for this. In addition, the present invention relates to uses of this method, as well as a computer program and a computer program product for implementing the method.

### BACKGROUND INFORMATION

Reliability requirements and safety requirements of, for example, vehicle functions come about from customer requests in conjunction with taking into consideration the technical, legal and financial boundary conditions. Reliability requirements in vehicle functions are specified, for instance, in the form of short repair times or long intervals between servicing. Reliability requirements, on the other hand, establish the reliable behavior of the vehicle in the case of failures and interferences of components of the vehicle. The reliability requirements and the safety requirements placed on vehicle functions also establish right from the beginning requirements on the technical implementation and accountability. One of the most powerful measures for increasing safety and reliability is redundancy. Since, increasingly, vehicle functions or parts of vehicle functions are being implemented by software, systematic methods for reliability analysis and safety analysis also have an increasing influence on the software development for electronic control units, for instance, on the implementation of monitoring concepts, diagnosis concepts and safety concepts.

For complex electronic systems, the activities for safeguarding reliability and safety have to be planned early, and have to be integrated into the entire project plan.

### SUMMARY OF THE INVENTION

Within the scope of the present application, by the concept “system”, the following should be understood, depending on the context: The smallest system section required for achieving a certain function, cooperating system sections up to the whole system or, on an even broader scope, the entire system, including the operating persons or other elements having an effect on the overall system. In order to explain the present invention, reference is made within the scope of the present Application essentially to systems that are a component part of vehicle control systems. This reference has a purely explanatory character, and is not intended to restrict the present invention in any way to such systems. The present invention has validity rather more generally with reference to software-based electronic systems.

For the purpose of checking the safety and reliability of such systems, the use of reliability functions has become known, with the aid of which the degree of reliability may be given for the required functions of the system. For the determination of such a reliability function, one may start from the reliabilities of the hardware components of the system that are necessary for the required system functions. Reliability analyses include, for instance, failure rate analyses and failure type analyses, such as the failure type analysis and effectiveness analysis (FMIA) or fault tree analysis (FTA). In the following, a reliability analysis in the light of a failure rate analysis shall be discussed, while calculating the reliability function in the light of a reliability block diagram for a system under discussion.

The systematic investigation of the failure rate of a unit under observation makes possible the prediction of the reliability for the unit under observation by calculation. This prediction is important for detecting trouble spots early, for evaluating alternative solutions and for measuring quantitatively the connections between reliability, safety and availability. In addition, investigations of this kind are necessary so as to be able to set reliability requirements, for instance, on system components.

As a result of neglect and simplification, as well as the uncertainty of the input data used, the calculated, predicted reliability is only able to be an estimated value for the true reliability, which can only be ascertained by reliability testing and field observations. Within the scope of comparative investigations in the analysis phase, however, the absolute accuracy is not important, so that, especially in the valuation of implementation alternatives, the calculation of the predicted reliability is useful.

In the following paragraphs, the unit observed is always a technical system or a system component of the vehicle. In the general case, the unit observed may also be framed more widely, and include the driver of the vehicle, for example.

Failure rate analysis (on this, see Alessandro Birolini: Reliability of Units and Systems, Springer Verlag, 1997) distinguishes the following steps:
specification of the boundaries and components of the technical system, of the required functions and of the requirement profile
setting up the reliability block diagram
determination of the load conditions for each component
determination of the reliability function or failure rate for each component
calculation of the reliability function for the system
removal of weak points

The failure rate analysis is a multi-step method and may be carried out “top down” from the system level via the various subsystem levels to the component level of the technical system architecture. After changes in the technical system architecture, the failure rate analysis has to be repeated.

What shall now be explained in greater detail is the first step of the failure rate analysis.

For the theoretical considerations which are necessary for predicting reliability, one should assume detailed knowledge of the system and its functions, as well as specific possibilities for improving the reliability and safety. The knowledge of the architecture of the system and its mode of operation, the working conditions and the load conditions for all system components, and the mutual interactions between the components, for instance, in the form of signal flows and the input view and output view of all components are all part of the understanding of the system.

Among the possibilities for improvement are the limitation or the reduction of the stress on the components during operation, such as the static or dynamic stresses, the stress of the interfaces, the use of better suited components, the simplification of the system design or component design, the pretreatment of critical components, as well as the use of redundancy.

The function called for specifies the object of the system. The establishment of system boundaries and functions called for forms the starting point of every reliability analysis, because with that failure is also defined.

In addition, the environmental conditions have to be defined for all components of the system, since they influence the reliability of the components. Thus, for example, the temperature range has a great influence on the failure rate of hardware components. In the vehicle, for instance, the required temperature range, use in moist conditions, dust or a corrosive atmosphere, or stresses due to vibration, shocks or fluctuations, such as, for instance, supply voltages are all a part of the environmental conditions. If the required functions and the environmental conditions are also a function of time, a requirements profile has to be established. An example of legally specified requirement profiles in the vehicle are test cycles for testing for compliance with exhaust gas regulations. In this connection, the term representative requirement profiles is also used.

The second step of failure rate analysis is explained in more detail below.

The reliability block diagram answers the questions as to which hardware components of a system basically have to function to satisfy the function called for, and which hardware components, in case of their failure, do not fundamentally impair the function, since they are present redundantly. Setting up the reliability block diagram is performed by observing the components of the technical system architecture. These components are connected in a block diagram in such a way that the components required to fulfill the function are connected in series, and redundant components are connected in parallel.

FIG. 1 schematically represents a so-called brake-by-wire system 1, brake pedal 2, control unit 3 as well as the four braking units, namely, braking unit 4, front left, braking unit 5, rear left, braking unit 6, front right and braking unit 7, rear right, being shown. The hardware components required for a function of system 1 are designated by K.

For a fictitious brake-by-wire system 1, as shown in FIG. 1, a system boundary is first established. The system is made up of the components brake pedal unit (K₁), control unit (K₂), wheel braking units (K₅, K₇, K₉, K₁₁) and electrical connections (K₃, K₄, K₆, K₈, K₁₀).

In brake-by-wire systems there is no hydraulic connection between the brake pedal and the wheel brakes, but rather an electrical one. During braking, the driver command, that is specified by brake pedal unit K₁ and is processed in control unit K₂, and the energy required for braking are transmitted “by wire” to wheel brake units K₅, K₇, K₉ and K₁₁. In this context, it must be ensured that taking over the functions “information transmission and energy transmission” between the pedal unit and the wheel brake units, which, in conventional braking systems, are implemented mechanically-hydraulically, does not introduce, by the electrical and electronic components K₂, K₃, K₄, K₆, K₈ and K₁₀ any additional safety risk, but rather brings with it a safety gain. The predictable transmission of the braking commands is therefore a necessary assumption. Likewise, safety has to be assured even in the case of interferences and the failure of components

The function “braking” shall now be discussed. The overall reliability of the system is to be determined for this. It is assumed that the failure rates λ₁ to λ₁₁ of components K₁ to K₁₁ are known.

This example is from now on greatly simplified. It is only intended to make clear the procedure of the reliability analysis in principle. Therefore, only the information transmission shall be described, whereas the aspects of the energy supply and the energy transmission, as well as driving dynamics boundary conditions, such as the necessary braking force distribution to the front and rear axle, which of course have to be taken into account in the reliability analysis, are disregarded.

For the fulfillment of the function “braking”, in this simplified view, the functioning of the components brake pedal unit K₁, control unit K₂ and the connections between the brake pedal unit and control unit K₃ are absolutely necessary.

In the wheel brake units and the connections between control unit and wheel brake units there is a redundancy. Under the greatly simplified assumption that a sufficient secondary braking effect for the vehicle may be achieved using only one wheel brake unit, then, for example, components K₄ and K₅ are necessary, while components K₆ and K₇, K₃ and K₉ and K₁₀ and K₁₁ are present redundantly. Such a device is also designated as a 1-in-4 redundancy.

Then the reliability block diagram for the function “braking” looks as represented in FIG. 2.

After establishing the load conditions and determining reliability functions Rᵢ(t) for all components Kᵢ, the reliability function of the system R_{S}(t) may be calculated, taking into consideration the basic rules shown in subsequent Table 3 for reliability block diagrams.

TABLE 3
Some basic rules for calculating the reliability function for the system:

| | | failure rate λₛ for | |
|---|---|---|---|
| | reliability function | λᵢ = constant: | |
| reliability block diagram | Rₛ = Rₛ(t), Rᵢ = Rᵢ(t) | (Rᵢ(t) = e^{-λit} | example |
| 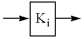 | Rₛ = Rᵢ | λₛ = λᵢ | |
| 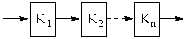 | 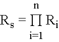 | 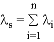 | R₁ = R₂ = 0.9 Rₛ = 0.9 · 0.9 = 0.81 |
| 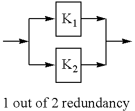 | 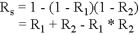 | | R₁ = R₂ = 0.9 Rₛ = 1 − (1 − 0.9)(1 − 0.9) = 0.99 |
| 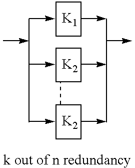 | R₁ = R₂ = . . . = Rₙ = R 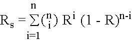 for k = 1, Rₛ = 1 − (1 −R)ⁿapplies | | Rᵢ = R₂ = R₃ = R₄ = 0.9 at 1 out of 4 Redundancy Rs = 1 − (1 − 0.9)⁴ = 0.9999 |

For the example in FIG. 2, the reliability function of system R_{S} may be calculated with it. Using the assumptions R₄=R₆=R₈=R₁₀ and R₅=R₇=R₉=R₁₁ it follows that for R₅:
R_{S}=R₁R₂R₃[1−(1−R₄R₅)⁴]

As this simplified example shows, the system reliability for a function increases by redundant components in the reliability block diagram compared to the component reliability. On the other hand, in the serially shown components, the system reliability decreases compared to the component reliability. Therefore, for the serial components in the reliability block diagram, one should require high reliability of the components, or introduce a technical system architecture which provides redundant structures here too.

Whereas, above, the calculation of the reliability function for a system for a certain system function called for has been represented in exemplary fashion and in a greatly simplified manner, it is desirable in the same way to be able to obtain statements concerning the safety of a system. For the safety of a system it is frequently irrelevant whether the unit being examined fulfills the required functions or not, if thereby no high risk comes up that is not justifiable. Software-based electronic systems, such as the ones being examined in the present Application, are made up mainly of hardware components as well as software components, the software components being usually able to be distributed to a few of the hardware components. There is a strong need to be able to check reliably the safety and the reliability of such software-based electronic systems.

According to the present invention, a reliability function is determined for calculating the reliability of at least one of the required functions of the system, and an additional reliability function is determined for calculating the reliability of at least one of the safety functions of the system, in the determination of these reliability functions software components of the system also being taken into consideration. In this context, the software components are also taken into consideration with the aid of the hardware components to which these software components have been distributed. In this context, this consideration may extend to the hardware component(s) itself (themselves) as well as to the corresponding hardware connections which are influenced by the respective software component (e.g. by the emission of an output signal). Thereby it is first possible to make statements about the safety and reliability of a software-based electronic system, these statements concerning the system made up of hardware components and software components including the respective connections and not being limited only to the hardware components.

Safety and reliability of the system including hardware components and the software components are checked, using a reliability function which, for instance, may be determined, as explained at the outset, with the aid of the reliability block diagram for the system. As will be explained below, according to the present invention, the software components of the system are also taken into consideration in the determination of the reliability function. This amounts to a new system definition, since up to the present, for reliability analyses, only a system made up of hardware components was examined, and the software components were submitted, if at all, to their own separate analysis.

Using the present invention, the early qualification of different monitoring concepts of electronic control units in particular, and of functions of electronics systems in general, which are implemented by software and hardware, is made possible with respect to the achievable system safety and system reliability. The results influence especially the distribution of software functions to the microcontrollers of networked control units, and therewith the development of software for distributed and networked control units.

In order to be able to make statements about the system as a whole, it is meaningful to check all functions of the system, that is, all required system functions and all safety functions of the system using determination of corresponding reliability functions.

Reliability functions, as a rule, take on a certain value range, such as from 0 to 1, and in the following, without limitation of the general validity, the assumption being made that a high value (1) stands for a high reliability and a low value (0) stands for a low one. The reliability functions according to the present invention relate, for one thing, to the reliability of the required system functions, and, for another thing, to the reliability of the safety functions of the system. After determination of the corresponding reliability functions it is advantageous to calculate the definite values of these reliability functions for the selected system architecture (or system configuration), in order to obtain definite statements about the reliability of the system functions and the safety functions.

As a rule, besides the selected system architecture, other configurations are also able to be implemented, which lead to the same required system functions. The same applies to the required safety functions. Therefore, for the selection of a suitable system architecture, it is of advantage if the reliability functions according to the present invention, are determined for various system architectures. In this context, the system architecture may be changed as follows: by establishment of the hardware components (type of hardware components, positioning and redundancies of these components) required for the implementation of the required system functions; establishment of the software components necessary for the implementation of the required system functions and safety functions, and finally, the assignment of the software components to determined hardware components. By the variation of one or more of these establishments or assignments, the system architecture may be changed.

In this connection it is meaningful to calculate the reliabilities (values of the reliability functions) for the system architectures revealed, and to give preference to configurations having a high reliability. The reliabilities calculated, may, in this connection relate either to the required system functions or to the safety functions of the system. However, it is advantageous to maximize both reliabilities, in order to find a system architecture which achieves high values both with respect to reliability and with respect to safety.

To increase the system safety, it is meaningful to control the required system functions by monitoring functions. Thereby one may take measures in time, in case a certain system function of the system may no longer be supplied. These measures extend from giving off a certain information all the way to switching off the entire system, in order to minimize possible risks.

The safety may be further increased in that the monitoring functions for the monitoring of the system functions are themselves monitored by system monitoring functions.

Furthermore, it is of advantage if the system monitoring functions monitor, at least in part, the system section which includes the monitoring functions for monitoring the system functions. Thereby, not only may the monitoring functions be controlled, but the whole system section (such as a microcontroller) may be controlled, and a failure of this system section may be detected.

It is also of advantage if the system monitoring functions are distributed to two system sections, of which one system section includes said monitoring functions as well as the required system functions, which are controlled by these monitoring functions. For, such a configuration makes possible the monitoring of the two system sections in any and all directions, especially a mutual monitoring of these system sections.

As will be explained in greater detail in the following, the method according to the present invention may be used with advantage, in a distributed and networked system (control unit) optimally to assign software components to hardware components (such as a microcontroller). Furthermore, the method according to the present invention is suitable for establishing the system architecture of a software-based electronic system, especially of a control unit, such as an engine control unit.

The method according to the present invention may be expediently implemented in practice for the mostly complex electronic systems that occur, using a computer program. This computer program determines the appertaining reliability functions in a given system architecture, and calculates from it the corresponding values for the reliability and safety of the system. In the case of implementation via a computer program, the system architecture may be particularly efficiently optimized, known optimization methods (such as the Monte Carlo method) being usable. When a reliability block diagram is used to determine the reliability functions, the computer program is able to ascertain quickly the corresponding reliability functions, using the basic rules shown at the outset (cf. top of table).

The computer programs can be stored on suitable storage media such as EEPROM's, flash memories, but also DVD's, CD ROM's, diskette drives or hard disk drives. Downloading the computer program via internal or publicly usable networks (Intranet or Internet) is also possible.

### BRIEF DESCRIPTION OF THE DRAWINGS

FIG. 1 shows a schematic representation of a brake-by-wire system as an example of an electronic system

FIG. 2 shows a reliability block diagram for the function “braking”, that appertains to the system shown in FIG. 1.

FIG. 3 shows the example of a sequence of steps in the reliability analysis and the safety analysis and in the specification of reliable and safe systems;

FIG. 4 schematically shows components of a control unit as an example of a distributed and networked system, which, according to the present invention, is monitored with respect to safety and reliability.

FIG. 5 shows various reliability block diagrams for functions of the system shown in FIG. 4.

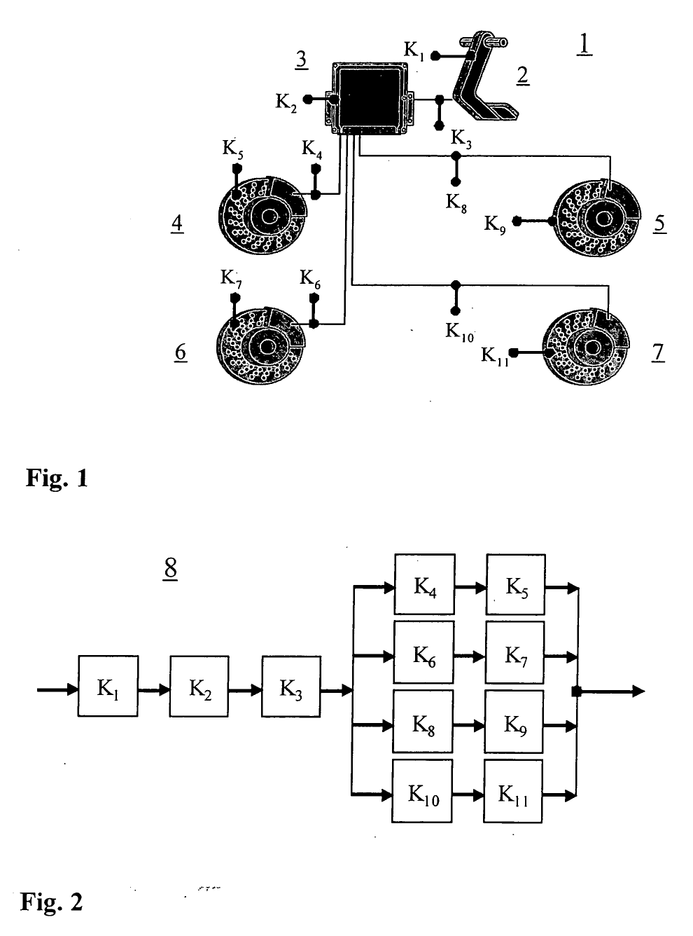

### DETAILED DESCRIPTION

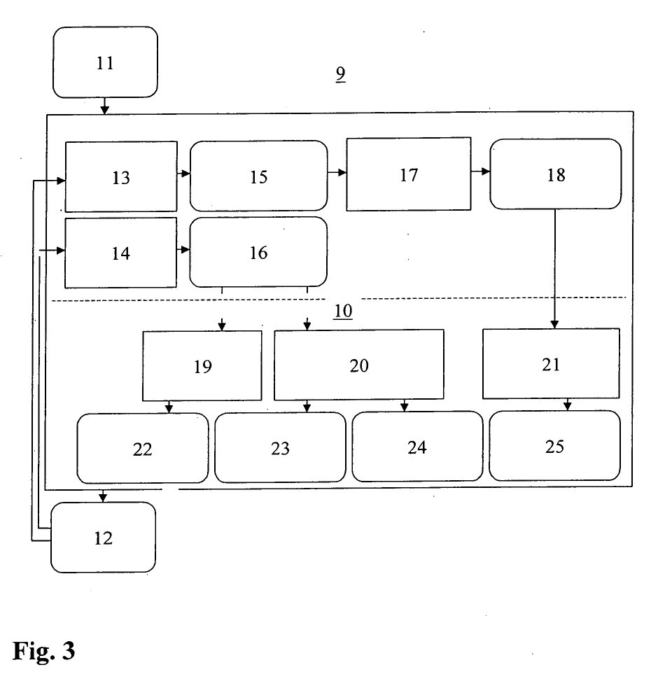

We now, first of all, show the steps involved in a reliability analysis and a safety analysis, in the light of the illustration in FIG. 3. In this context, iterative and connected processes having several steps are involved. They have an influence on the requirements on the hardware, software and the software development process for electronic systems. In this instance, methods for failure type analysis, such as FMEA or FTA are used also for the safety analysis. Failure type analysis yields a valuing of the risks for all functions of the system.

The admissible boundary risk is, as a rule, specified implicitly by safety technology establishments, such as laws, norms or regulations. From the ascertained risk for the functions of the system and the admissible boundary risk, safety technological requirements on the system are then derived, for instance, with the aid of norms such as IEC 61508, which often have a great influence on the system design, the hardware design and the software design in the development of the electronic system.

For the so-called safety-relevant functions of the system, that are determined and limited by the failure type analysis, special protective measures have to be taken which may be implemented, for example, in hardware and software.

In detail, FIG. 3 shows two main blocks 9 and 10, first main block 9 relating to the reliability analysis and the safety analysis, and second main block 10 relating to the specification of reliable and safe systems. Into the reliability analysis and the safety analysis (main block 9) goes, on the one hand, logical system architecture 11, and, on the other hand, technical system architecture 12. Technical system architecture 12, on its part, is a result of the system specification, a changed system specification (system architecture) giving rise to a renewed reliability analysis and safety analysis.

At the beginning of the reliability analysis and the safety analysis, there is, on the one hand, danger analysis 13, and, on the other hand, the identification of relevant components and subsystems (the block designated by 14). From danger analysis 13 are derived the specific dangerous situations 15, and, connected with that, risk failure type analysis and risk failure rate analysis, as was explained in detail in the introduction to the specification. The results of this analysis 17 are the reliability requirements and the safety requirements 18 on the system. On the other side, as the result of identification 14 of relevant components and subsystems, one obtains the reliability-relevant and the safety-relevant components and subsystems 16 of the system.

From the two results of the reliability analysis and the safety analysis, namely the reliability-relevant and the safety-relevant components and subsystems 16, as well as the reliability requirements and the safety requirements 18 on the system, a necessary and possible system specification (main block 10) is derived. The relevant components and subsystems influence definition 19 of the verification process and the validation process, and definition 20 of the requirements on the technical components and subsystems. Reliability requirements and safety requirements 18 on the system influence the definition of the software development process (block 21).

Specific results, in this instance, are verification process and validation process 22, reliability requirements and safety requirements 23 on the hardware, reliability requirements and safety requirements 24 on the software, as well as the actual software development process 25.

These four results lead to the overall result of technical system architecture 12. This technical system architecture may be corrected under certain circumstances and the enumerated steps may thereupon be repeated, in order to check whether the changed system architecture leads to a system of greater reliability and safety.

The verification of the safety and reliability of these monitoring concepts is the supposition for admitting vehicles to street traffic. In the following, using the example of the monitoring concept for an e-gas system, the method is shown for judging the reliability and safety of the monitoring concept, using reliability block diagrams.

As a possible danger for an e-gas system, an undesired giving of gas and an accident resulting from it shall be assumed. For the engine control unit, this means that all those control functions and regulation functions f, are safety relevant which may lead to an unintentional increase in the engine torque. Therefore, for these functions, a monitoring concept is essential.

In this example, the somewhat simplified monitoring concept will be explained, as has been used for years in engine control units, with regard to safety and reliability, with the aid of the method according to the present invention. Within the scope of the working group “e-gas” of the Verband der Automobilindustrie (VDA) (Association of the Automobile Industry), this basic concept developed by the firm of Robert Bosch GmbH is currently being refined to a standardised monitoring concept for the engine controls of Otto and Diesel engines.

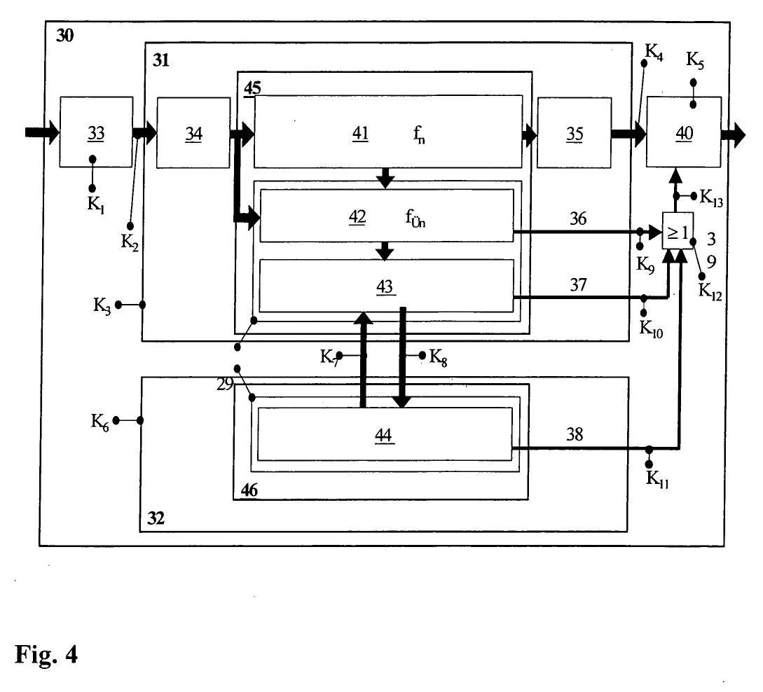

FIG. 4 shows the monitoring concept for safety-relevant control functions and regulating functions fₙ.

In FIG. 4, a control unit 30 is shown as a software-based electronic system. A first microcontroller 31 is used as a functional computer, while a second microcontroller 32 is used as a monitoring computer. Signals arrive at input stage 33 of control unit 30, and from there they are conducted to A/D converter 34 in microcontroller 31. The digitized signal triggers the actual control functions and regulating functions fₙ (block 41). In parallel, signals are conducted to block 42, which includes the functions for monitoring the control functions and regulating functions f_{Ün}. Block 41 is connected to block 42 for the monitoring of the control functions and the regulating functions. The named monitoring functions f_{Ün}, their part, are checked by functions for monitoring the microcontroller, that is, by the so-called system monitoring functions. For this purpose, block 42 is connected to block 43. Blocks 41, 42 and 43 are components of software 45 of microcontroller 31. Blocks 42 and 43 have pure monitoring functions.

Furthermore, shown in FIG. 4 is microcontroller 32 used as a monitoring computer, to whose software 46 the functions for monitoring the microcontroller (block 44) also belong. From this it may be seen that these functions for monitoring the microcontroller (system monitoring functions) are distributed to the two microcontrollers 31 and 32. We shall go into details on this below. Blocks 42, 43 and 44 represent monitoring functions 29.

Control functions and regulating functions fₙ (block 41) executed by the control unit are applied to D/A converter 35, whose output is at output stage 40, in the form of an output signal. Outputs 36, 37 and 38 of blocks 42, 43 or 44 that take care of the monitoring are supplied to an adding element 39, so that the detection of an error by one of the three blocks 42, 43 or 44 leads to a corresponding output signal of adding element 39. The latter is connected to output stage 40, whereby, depending on the kind of the error, specified influence may be exerted on the output stage.

In the following, the function of the monitoring concept shown in FIG. 4 will be explained more closely.

The safety-relevant control functions and regulating functions fₙ are constantly monitored by monitoring functions f_{Ün}. Monitoring functions f_{Ün}, use the same input variables as the control functions and regulating functions fₙ, but operate using different data and using different algorithms.

The functions for monitoring the microcontroller (=system monitoring functions), besides checking RAM functions, ROM functions and microprocessor functions, for example, also check whether control functions and regulating functions fₙ and monitoring functions f_{Ün} are being carried out at all. In this example, this makes necessary the use of a second microcontroller 32 in engine control unit 30, a so-called monitoring computer. The functions for monitoring microcontroller 31, 32 are distributed to the function computer and the monitoring computer. The two monitor each other preferably in a question-answer game.

In this exemplary embodiment, cutting off the current for the electromechanical throttle valve is established as a safe state. The throttle valve is constructed in such a way that it automatically takes up the idling position after a power cut-off. The transition into the safe state may therefore be initiated by cutting off output stages 40 of the control unit, which activate the throttle valve. Thus, in operation under emergency conditions, the engine may continue to be operated.

Both monitoring functions f_{Ün} and the functions for monitoring the microcontroller on the function computer and the monitoring computer may, thus, switch off the throttle valve output stages of control unit 30. In the case of a detected error, besides this safety reaction, an entry into the error memory is also made. In addition, mostly information is also output to the driver, for instance, via a display in the instrument cluster.

If a judgment is to be made on the reliability of this monitoring concept, a differentiation must first be made between three kinds of function:
control functions and regulating functions fₙ
monitoring functions f_{Ün}
the functions for monitoring the microcontroller (=system monitoring functions)

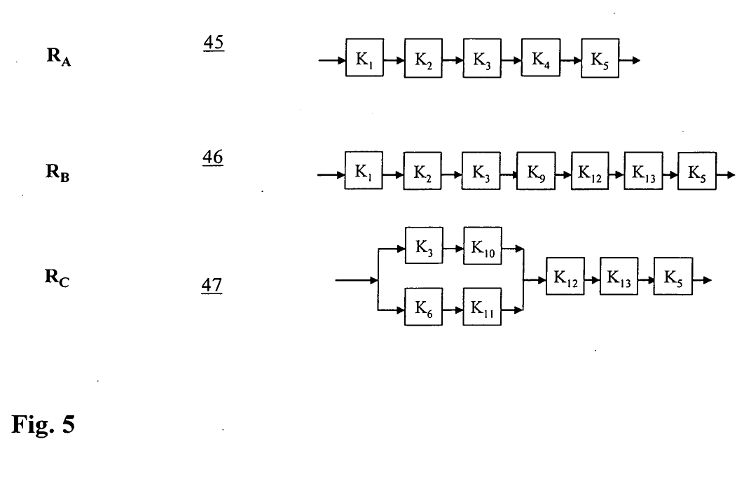

Reliability block diagrams 45, 46, 47 for these different functions are then rather easily determined, and are shown in FIG. 5.

In order to determine the system reliability, one will call for all three types of function at the same time. Then the system reliability is yielded by a series connection of these block diagrams. In addition, components K₇ and K₈ (connection of blocks 43 and 44 in FIG. 4), which do not occur in the block diagrams of the individual functions, also must be connected in series.

System reliability R_{S reliability} is yielded by multiplication of the reliability of the three functions R_{X}; _{X=A, B, C} by the reliability of components K₇ R_{D} and K₈ R_{E}, and because of R_{X}<1, it is in each case less than the respective reliability of functions R_{X}. During the calculation of the system reliability, the rules for the calculation using elements that appear several times in the reliability block diagrams must be observed (cf. Alessandro Birolini: Reliability of Units and Systems, reference above).
R_{S reliability}=R_{A}R_{B}R_{C}R_{D}R_{E}

By contrast, for safety, only the reliable detection of a failure and the reliable transition into the safe state are required. The reliability R_{S} safety of this safety reaction is specified by the reliability of the monitoring functions f_{Ün} or of the functions for monitoring the microcontroller, and is therefore greater than the reliability of the functions R_{X}. In addition, the reliability of components K₇ R_{D} and K₈ R_{E} does not go into the calculation of R_{S safety}.

The reliability function for the reliability of the safety function (reaction) is as follows:
R_{S safety}=1−(1−R_{B})(1−R_{C})

As this example shows, measures for increasing safety are able to lower the reliability of the system. In addition, it may be seen that measures for increasing the reliability may lead to a reduction in safety of a system.

Although, in the method according to the present invention, basically only hardware components and hardware connections are being examined, the reliability analyses and the safety analyses have a great influence on software development. As shown in the example on the valuation of the monitoring concept, they influence, for instance, the assignment of the software function to the microcontrollers in a distributed and networked system, or the necessary quality assurance measures in the software development. This is an enormous advance compared to the related art, and leads to great advantages in the system development.

The method according to the present invention makes possible the following procedure for checking the safety and reliability of software-based electronic systems (cf. FIGS. 4 and 5):

Step 1: establishing the hardware network of the electronic system, i.e. especially specifying microcontrollers 31, 32 and their networking;

Step 2: establishing software components 41-44 which are required for the implementation of the functions of the electronic system, and specifying the communication between software components 41-44.

Step 3: assigning software components 41-44 to microcontrollers 31, 32 of the hardware network;

Step 4: setting up reliability block diagrams 45-47 for the required functions of electronic system 30, starting from the hardware components and hardware connections K₁, i=1, . . . , 13;

Step 5: verifying the safety and reliability by the calculation of reliability for the safety functions and the reliability for all the required functions of electronic system (30);

Step 6: if necessary, repeating steps 1 through 5 and correcting the system architecture, that is, of the software network and the hardware network, as well as the assignment of the software components to hardware components.

1.-18. (canceled)

19. A method for checking a safety and a reliability of a software-based electronic system, comprising:
determining a first reliability function for checking a function of the software-based electronic system that is called for, based on required hardware components of the software-based electronic system, the first reliability function calculating a reliability of the function of the software-based electronic system; and
determining a second reliability function for calculating a reliability of at least one safety function of the software-based electronic system, wherein:
in order to determine the first reliability function and the second reliability function, software components of the software-based electronic system are taken into joint consideration, with the aid of the hardware components to which the software components are distributed.

20. The method as recited in claim 19, wherein at least one of the first reliability function and the second reliability function is determined for all functions of the software-based electronic system.

21. The method as recited in claim 19, wherein at least one of the first reliability function and the second reliability function is determined for all safety functions of the software-based electronic system.

22. The method as recited in claim 19, wherein values of the first reliability function and the second reliability function are calculated for a certain system architecture.

23. The method as recited in claim 22, wherein:
the system architecture is changed by at least one of the following components:
an establishment of the hardware components necessary for implementing the system functions and the safety functions called for,
an establishment of the software components necessary for implementing the system functions and the safety functions called for, and
an assignment of the software components to hardware components.

24. The method as recited in claim 22, wherein the system architecture is optimized with the aid of a maximization of the calculated reliabilities for the system functions called for at different system architectures.

25. The method as recited in claim 22, wherein the system architecture is optimized with the aid of a maximization of the calculated reliabilities for the safety functions of the software-based electronic system at various system architectures.

26. The method as recited in claim 19, wherein a reliability function is determined using a reliability block diagram.

27. The method as recited in claim 19, wherein the system functions called for are monitored by monitoring functions for monitoring these system functions, the monitoring functions, on their part, being monitored by system monitoring functions.

28. The method as recited in claim 27, wherein the system monitoring functions at least partially monitor the system section which includes the monitoring functions for monitoring the system functions.

29. The method as recited in claim 28, wherein the system monitoring functions are distributed to two system sections, of which one system section includes the system functions called for, as well as their monitoring functions.

30. The method as recited in claim 29, wherein both system sections monitor each other via the system monitoring functions.

31. The method as recited in claim 19, wherein in order to check the safety and the reliability of the software-based electronic system:
establishing the hardware components of the software-based electronic system and their networking, including specifying the microcontrollers and their networking;
establishing software components of the software-based electronic system, which are required for implementing the system functions and the safety functions of the software-based electronic system, and specifying the communication between the software components;
assigning the software components to hardware components, especially to the microcontrollers of the software-based electronic system;
setting up reliability block diagrams for the functions of the software-based electronic system called for, including the safety functions, starting from the hardware components and hardware connections; and
calculating the reliability for the safety functions and the reliability for all the functions of the software-based electronic system called for, for the verification of the safety and the reliability of the software-based electronic system.

32. The method as recited in claim 31, wherein as an additional step, the system architecture, that is, the software network and the hardware network, as well as the assignment of the software components to hardware components is corrected, and the steps according to claim 13 are repeated.

33. The method as recited in claim 19, wherein the method is used for assigning of software components to hardware components, such as microcontrollers, in a distributed and networked system.

34. The method as recited in claim 19, wherein the method is used for establishing the system architecture of a control unit including an engine control unit.

35. A computer program having program code that when executed results in a performance of the following:
determining a first reliability function for checking a function of a software-based electronic system that is called for, based on required hardware components of the software-based electronic system, the first reliability function calculating a reliability of the function of the software-based electronic system; and
determining a second reliability function for calculating a reliability of at least one safety function of the software-based electronic system, wherein:
in order to determine the first reliability function and the second reliability function, software components of the software-based electronic system are taken into joint consideration, with the aid of the hardware components to which the software components are distributed.

36. The computer program as recited in claim 35, wherein the computer program is included in a computer program product.
